(19) United States
(12) Patent Application Publication
(10) Pub. No.: US 2026/0312422 A1
(43) Pub. Date: Oct. 8, 2026

(54) POWER SUPPLY DEVICE AND OPERATION METHOD THEREOF

(71) Applicant: SK hynix Inc., Gyeonggi-do (KR)

(72) Inventors: Eun Kyu CHOI, Gyeonggi-do (KR); Dong Jun KIM, Gyeonggi-do (KR); Hyeong Rak KIM, Gyeonggi-do (KR)

(21) Appl. No.: 19/353,072

(22) Filed: Oct. 8, 2025

(30) Foreign Application Priority Data
Apr. 2, 2025 (KR) 10-2025-0042943

(51) Int. Cl. H02J 9/06; G01R 31/3835; H02J 7/80; H02J 7/90; G11C 5/14

(52) U.S. Cl. CPC H02J 9/061; G01R 31/3835; H02J 7/80; H02J 7/933; G11C 5/141

(57) ABSTRACT

A power supply device includes: a main power supply configured to be supplied with external power to output charging power and main power; an auxiliary power supply configured to be charged from the charging power to output auxiliary power; and a charging circuit configured to measure a charged voltage based on the auxiliary power, and perform, when the charged voltage exceeds a reference voltage, a monitoring operation on the auxiliary power to generate a monitoring result.

### CROSS-REFERENCE TO RELATED APPLICATION

The present application claims priority under 35 U.S.C. § 119(a) to Korean patent application number 10-2025-0042943, filed on Apr. 2, 2025, the entire disclosure of which is incorporated herein by reference.

### BACKGROUND

### 1. Technical Field

Various embodiments of the present disclosure generally relate to a power supply device, and more particularly, to a power supply device including an auxiliary power supply device, and a method of operating the same.

### 2. Related Art

A memory system may include a memory device in which data is stored, a controller which controls the memory device, and a power supply device which supplies power to the controller and the memory device.

The power supply device may include a main power supply device and an auxiliary power supply device. The main power supply device is configured to receive external power and supply internal power to the controller and the memory device, and the auxiliary power supply device is configured to supply auxiliary power when the main power supply device fails to output the internal power.

A Sudden Power Off (SPO) may occur in which the power supplied to the memory system is abruptly interrupted while the memory system is in operation. In this case, the auxiliary power supply device may temporarily supply auxiliary power to the controller and the memory device. To respond to such SPO, a method for monitoring the auxiliary power supply device has been discussed.

### SUMMARY

Various embodiments of the present disclosure are directed to a power supply device capable of monitoring an auxiliary power supply and an operation method thereof.

A power supply device according to an embodiment of the present disclosure may include: a main power supply configured to be supplied with external power to output charging power and main power; an auxiliary power supply configured to be charged from the charging power to output auxiliary power; and a charging circuit configured to measure a charged voltage based on the auxiliary power, and perform, when the charged voltage exceeds a reference voltage, a monitoring operation on the auxiliary power to generate a monitoring result.

A method of operating a power supply device according to an embodiment of the present disclosure may include: charging auxiliary power in an auxiliary power supply using charging power applied to the auxiliary power supply; comparing charged voltage based on the auxiliary power with a reference voltage to activate a reference signal; and performing, according to activation of the reference signal, a monitoring operation on the auxiliary power supply to generate a monitoring result.

A power system according to an embodiment of the present disclosure may include: a main power supply configured to be supplied with external power to output charging power and main power; an auxiliary power supply configured to be charged with the charging power to output auxiliary power; a charging circuit configured to measure a charged voltage based on the auxiliary power, perform, when the charged voltage exceeds a reference voltage, a monitoring operation on the auxiliary power to generate a monitoring result; and a controller configured to control the charging circuit.

### BRIEF DESCRIPTION OF THE DRAWINGS

FIG. 1 is a diagram illustrating a power system according to an embodiment of the present disclosure;

FIG. 2 is a diagram illustrating an operation of a power system according to an embodiment of the present disclosure;

FIG. 3 is a diagram illustrating a configuration of a charging circuit, according to an embodiment of the present disclosure;

FIG. 4 is a diagram illustrating a case where a controller controls a charging circuit, according to an embodiment of the present disclosure;

FIG. 5 is a diagram illustrating a method by which a monitoring circuit communicates with a controller, according to an embodiment of the present disclosure;

FIG. 6 is a diagram illustrating a method by which a charging circuit generates a reference signal, according to an embodiment of the present disclosure;

FIG. 7 is a diagram illustrating a method by which a charging circuit repeatedly performs a monitoring operation;

FIG. 8 is a diagram illustrating a voltage change in a charged voltage and a reference signal during a monitoring operation, according to an embodiment of the present disclosure;

FIG. 9 is a diagram illustrating a voltage change in a charged voltage and a reference signal during a monitoring operation, according to an embodiment of the present disclosure;

FIG. 10 is a diagram illustrating a memory card system to which a power supply is applied, according to an embodiment of the present disclosure; and

FIG. 11 is a diagram illustrating a storage system to which a power supply is applied, according to an embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure can be implemented in various forms and replaced with other equivalent embodiments, and they should not be construed as being limited to the specific embodiments set forth herein.

Hereinafter, the terms such as “first” and “second” may be used to describe various components. However, the components should not be limited by these terms. The above terms are used to distinguish one component from another component.

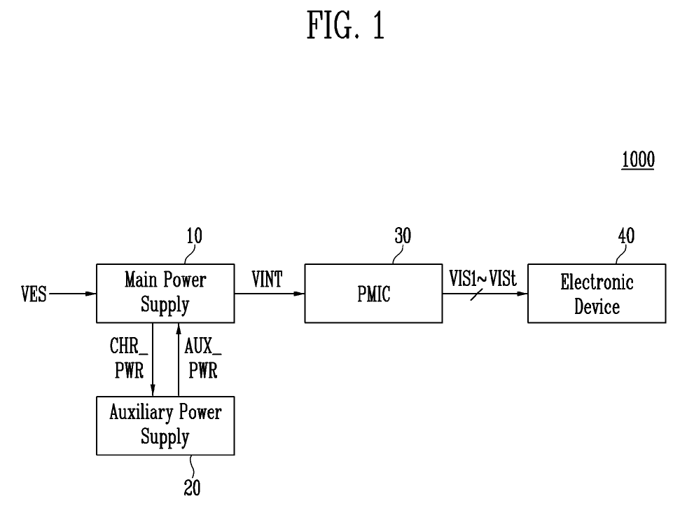

FIG. 1 is a diagram illustrating a power system 1000 according to an embodiment of the present disclosure.

Referring to FIG. 1, the power system 1000 may include a main power supply 10, an auxiliary power supply 20, a power management integrated circuit (PMIC) 30, and an electronic device 40. The main power supply 10 and the auxiliary power supply 20 may be referred to a power supply device.

The main power supply 10 may be configured to receive external power VES and output charging power CHR_PWR and operating power VINT. The main power supply 10 may provide the external power VES to the auxiliary power supply 20 and the power management integrated circuit 30.

The main power supply 10 may provide the external power VES to the power management integrated circuit 30 as the operating power VINT is operating normally.

The auxiliary power supply 20 may provide auxiliary power AUX_PWR to the power management integrated circuit 30 as the operating power VINT when the main power supply 10 is not operating normally. For example, the auxiliary power supply 20 may include an energy storage device. The auxiliary power supply 20 may be configured to charge the energy storage device thereof with the auxiliary power AUX_PWR from the charging power CHR_PWR and output the auxiliary power AUX_PWR. For example, the energy storage device may include a plurality of capacitors. For example, the auxiliary power supply 20 may provide the auxiliary power AUX_PWR to the power management integrated circuit 30 as the operating power VINT upon detecting an interruption in the supply of the external power VES.

The operating power VINT may be selected from either main power provided by the main power supply 10 via the external power VES or the auxiliary power AUX_PWR provided by the auxiliary power supply 20 via the charging power CHR_PWR. For example, the main power supply 10 may be supplied with the external power VES and provide the main power to the power management integrated circuit 30 as the operating power VINT. For example, the auxiliary power supply 20 may be charged with the charging power CHR_PWR to provide the auxiliary power AUX_PWR to the power management integrated circuit 30 as the operating power VINT.

The power management integrated circuit 30 may convert a level of the operating power VINT to generate one or more internal voltages VIS1 to VISt having the same or different levels. The plurality of internal voltages VIS1 to VISt may each be applied to the electronic device 40.

The electronic device 40 may include a processor and a memory for controlling the overall operation of the power system 1000. For example, the electronic device 40 may output data stored in the power system 1000 to the outside of the power system 1000 using the plurality of internal voltages VIS1 to VISt, and may receive data from the outside of the power system 1000.

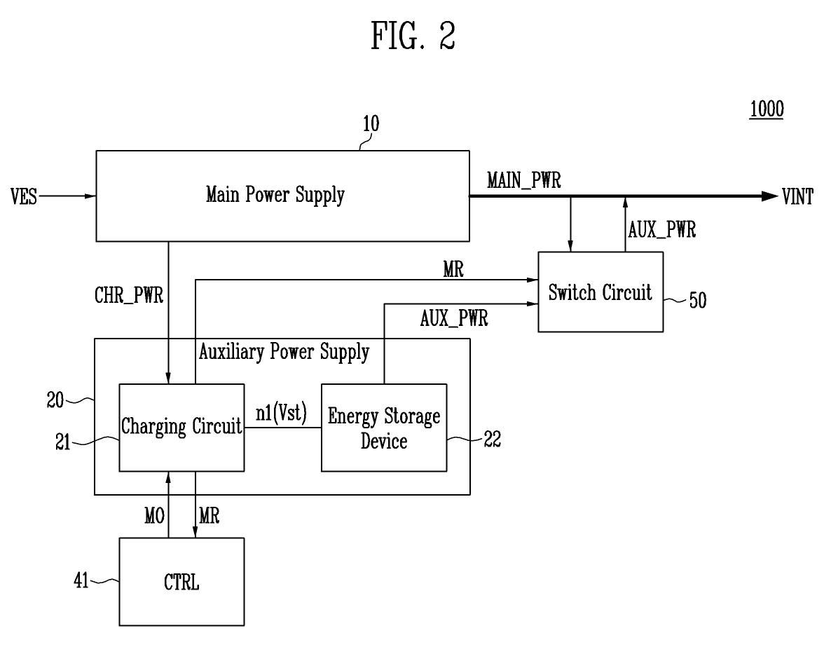

FIG. 2 is a diagram illustrating an operation of the power system 1000 according to an embodiment of the present disclosure.

Referring to FIG. 2, the power system 1000 may be configured to output main power MAIN_PWR or the auxiliary power AUX_PWR as the operating power VINT, based on the state of the auxiliary power supply 20.

The main power supply 10 may be configured to receive the external power VES and output the charging power CHR_PWR and the main power MAIN_PWR. For example, the main power MAIN_PWR may be used as the operating power VINT.

The auxiliary power supply 20 may include a charging circuit 21 and an energy storage device 22. The auxiliary power supply 20 may be configured to receive the charging power CHR_PWR from the main power supply 10 to charge the auxiliary power AUX_PWR.

The charging circuit 21 may be configured to output a monitoring result signal MR based on the status of the energy storage device 22. According to an embodiment, the charging circuit 21 may be configured to output the monitoring result signal MR based on a charged voltage Vst of the energy storage device 22. The charged voltage Vst may be a voltage based on the auxiliary power AUX_PWR charged by the auxiliary power supply 20. For example, the charging circuit 21 may be configured to check the charged voltage Vst while charging of the energy storage device 22 is in progress, and to monitor the status of the energy storage device 22 based on changes in the charged voltage Vst. For example, the charging circuit 21 may be configured to check the charged voltage Vst based on a monitoring signal MO from a controller (CTRL) 41.

The energy storage device 22 may include a plurality of capacitors. For example, the plurality of capacitors may be configured to be charged with the charging power CHR_PWR via the charging circuit 21 to output the auxiliary power AUX_PWR. For example, the energy storage device 22 may include one or more of electrolytic capacitors, film capacitors, tantalum capacitors, or ceramic capacitors.

When the energy storage device 22 is defective, the auxiliary power supply 20 might not be able to provide sufficient auxiliary power AUX_PWR in the event that the output of the main power MAIN_PWR is interrupted or rapidly reduced in level. For example, one or more of the plurality of capacitors of the energy storage device 22 may be short-circuited and the energy storage device 22 might not be charged normally. According to an embodiment, the charging circuit 21 may be configured to monitor the status of the energy storage device 22 based on the monitoring signal MO from the controller 41. The charging circuit 21 may be configured to transfer the monitoring result signal MR to the controller 41 based on the status of the energy storage device 22. For example, the charging circuit 21 may be configured to control a current flowing to the energy storage device 22 based on the status of the energy storage device 22. The charging circuit 21 may be configured to monitor a current, voltage, and temperature corresponding to the energy storage device 22, and to detect various types of defects in the energy storage device 22 based on the monitoring results. The charging circuit 21 may be configured to cut off a current flowing through the energy storage device 22 where defects are detected.

A switch circuit 50 may be configured to monitor the level of the main power MAIN_PWR output from the main power supply 10 and output the auxiliary power AUX_PWR as the operating power VINT when the output of the main power MAIN_PWR is interrupted or rapidly reduced in level. For example, the switch circuit 50 may be configured to output the auxiliary power AUX_PWR instead of the main power MAIN_PWR based on the monitoring result signal MR. For example, the monitoring result signal MR may include status information about whether the auxiliary power supply 20 is functioning normally. Based on the monitoring result signal MR, the switch circuit 50 may not output the auxiliary power AUX_PWR even when the supply of the main power MAIN_PWR is interrupted. For example, the switch circuit 50 may be activated based on the monitoring result signal MR and configured to output the auxiliary power AUX_PWR when the supply of the external power VES is interrupted.

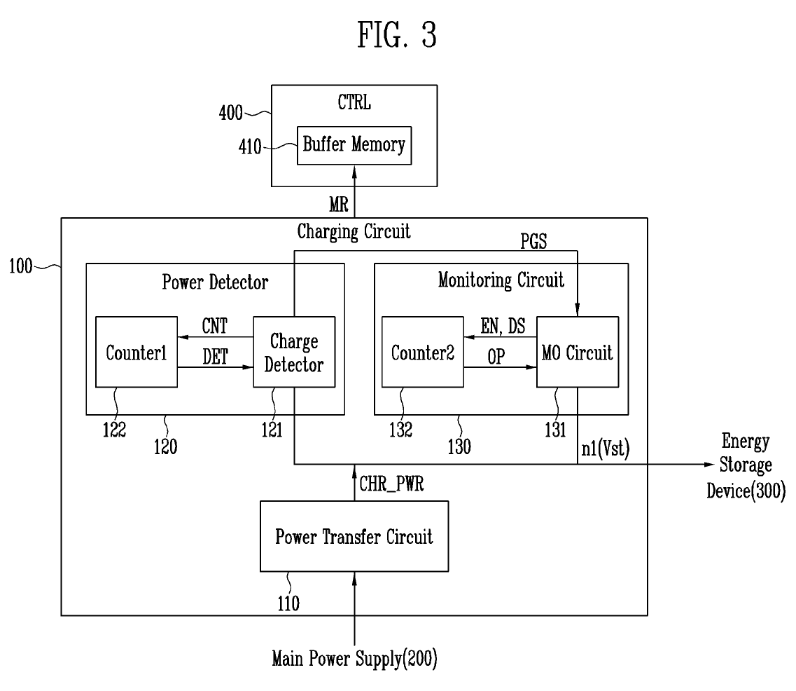

According to an embodiment, the charging circuit 21 may be configured to monitor the status of the energy storage device 22 without the control of the controller 41. The charging circuit 21 may be configured to monitor the status of the energy storage device 22 without the monitoring signal MO from the controller 41. For example, the controller 41 may be a component included in the electronic device 40 of FIG. 1. For example, as the charging circuit 21 monitors the status of the energy storage device 22 without the control of the controller 41, the resource consumption of the controller 41 for controlling the energy storage device 22 may be minimized or reduced. Thus, the overhead of the controller 41 may be reduced. A specific description of the operation of the charging circuit 21 to monitor the status of the energy storage device 22, without the control of the controller 41, will be described below with reference to FIGS. 3 to 9.

FIG. 3 is a diagram illustrating a configuration of a charging circuit 100, according to an embodiment of the present disclosure.

Referring to FIG. 3, the charging circuit 100 may be configured to measure the charged voltage Vst stored in an energy storage device 300 and, when the charged voltage Vst exceeds a reference voltage, perform a monitoring operation on the energy storage device 300 to generate the monitoring result signal MR. The energy storage device 300 may correspond to the energy storage device 22 discussed herein above.

The charging circuit 100 may include a power transfer circuit 110, a power detector 120, and a monitoring circuit 130.

The power transfer circuit 110 may be configured to receive the charging power CHR_PWR from a main power supply 200 and transfer the charging power CHR_PWR to a first node n1. For example, based on the charging power CHR_PWR transferred by the power transfer circuit 110, the energy storage device 300 may be charged with the auxiliary power.

The power detector 120 may include a charge detector 121 and a first counter (Counter1) 122. The power detector 120 may be configured to check the charged voltage Vst at the first node n1 when a voltage is applied to the first node n1.

The charge detector 121 may check the voltage at the first node n1. For example, the charge detector 121 may perform a checking operation to determine whether a level of the charged voltage Vst detected from the first node n1 has increased to a level of a reference voltage. For example, the reference voltage may be set to a voltage less than a maximum charged voltage of the energy storage device 300. For example, the reference voltage may be set to a voltage which is 5% to 15% less than the maximum charged voltage of the energy storage device 300.

According to an embodiment, the charge detector 121 may be configured to generate a reference signal PGS by checking the charged voltage Vst. For example, the charge detector 121 may determine that charging has proceeded normally when the charged voltage Vst is equal to or greater than the reference voltage, and may determine that charging has not proceeded normally when the charged voltage Vst is equal to or less than the reference voltage. For example, the power detector 120 may be configured to generate the high-level reference signal PGS when the charged voltage Vst is equal to or greater than the reference voltage, and the low-level reference signal PGS when charged voltage Vst is equal to or less than the reference voltage. For example, when the charged voltage Vst at the first node n1 is less than the reference voltage, the charge detector 121 may be configured to output a count signal CNT to the first counter 122.

The first counter 122 may be configured to receive the count signal CNT output from the charge detector 121, compare a count time to a reference time, and output a detection signal DET. For example, the count signal CNT may include information about the count time. The count time may refer to a time period between the time point when the charging power CHR_PWR begins to be supplied by the power transfer circuit 110 and the time point when the charge detector 121 outputs the count signal CNT. For example, the first counter 122 may be configured to output the high-level detection signal DET when the reference time is longer than the count time, and the low-level detection signal DET when the count time is longer than the reference time.

According to an embodiment, based on the detection signal DET received from the first counter 122, the charge detector 121 may check the charged voltage Vst at the first node n1 again. For example, when the reference time is longer than the count time, the charge detector 121 may check the charged voltage Vst at the first node n1 again. For example, when the count time is longer than the reference time, the charge detector 121 may determine that the charging operation is abnormal. In this case, the charging circuit 100 may be configured to send the monitoring result signal MR to a controller (CTRL) 400 indicating that the auxiliary power supply is abnormal.

The monitoring circuit 130 may include a monitoring operation (MO) circuit 131 and a second counter (Counter2) 132.

The monitoring operation circuit 131 may be configured to perform a monitoring operation on the energy storage device 300 via the first node n1. For example, the monitoring operation circuit 131 may be configured to perform the monitoring operation by measuring a storage capacity of the energy storage device 300, measuring a transfer efficiency, or measuring an energy loss value.

According to an embodiment, the monitoring operation circuit 131 may be configured to perform a monitoring operation on the energy storage device 300 by discharging the energy storage device 300 to measure the time period during which the charged voltage Vst drops from a first voltage to a second voltage. For example, the monitoring operation circuit 131 may be configured to measure a storage capacity of the energy storage device 300 based on the time period during which the charged voltage Vst drops from the first voltage to the second voltage. For example, the monitoring operation circuit 131 may control the energy storage device 300 to be charged further before discharging the energy storage device 300 to increase the level of the charged voltage Vst. For example, when one or more of the capacitors included in the energy storage device 300 are short-circuited, the capacitance of the energy storage device 300 may change. When the capacitance of the energy storage device 300 changes, the monitoring operation circuit 131 may be configured to determine whether the energy storage device 300 is in a normal state based on the discharge time.

According to an embodiment, the monitoring operation circuit 131 may be configured to perform the monitoring operation on the energy storage device 300 when the charged voltage Vst exceeds the reference voltage. For example, the monitoring operation circuit 131 may be configured to perform the monitoring operation based on the reference signal PGS received from the charge detector 121. For example, when the charged voltage Vst exceeds the reference voltage, the reference signal PGS may be activated. For example, the reference signal PGS may transition from a low level to a high level when the reference signal PGS is activated. The monitoring circuit 130 may be configured to perform the monitoring operation based on a rising edge (activation) of the reference signal PGS. For example, the monitoring operation circuit 131 may be configured to perform the monitoring operation without the control of the controller 400 and transfer the monitoring result signal MR including a result for the monitoring operation to the controller 400.

According to an embodiment, the monitoring operation circuit 131 may be configured to suspend the monitoring operation when the charged voltage Vst is equal to or less than the reference voltage. For example, the monitoring circuit 130 may be configured to suspend the monitoring operation based on a falling edge (deactivation) of the reference signal PGS. For example, the monitoring operation circuit 131 may be configured to resume the monitoring operation based on the charged voltage Vst exceeding the reference voltage again or based on the rising edge of the reference signal PGS.

According to an embodiment, the monitoring operation circuit 131 may be configured to perform the monitoring operation repeatedly with a first period (i.e., every first period), after a first time has elapsed since the charged voltage Vst exceeds the reference voltage. For example, the monitoring operation circuit 131 may be configured to transfer an enable signal EN to the second counter 132 when the charged voltage Vst exceeds the reference voltage. For example, the enable signal EN received by the second counter 132 may be at a high level. For example, the second counter 132 may be configured to transfer an operation signal OP to the monitoring operation circuit 131 repeatedly with the first period, after the first time has elapsed since the enable signal EN is received. For example, the monitoring operation circuit 131 may be configured to perform the monitoring operation upon receiving the operation signal OP.

According to an embodiment, the monitoring operation circuit 131 may be configured to perform the monitoring operation repeatedly with the first period, after the first time has elapsed from the rising edge of the reference signal PGS. For example, when the charged voltage Vst exceeds the reference voltage, the reference signal PGS may be activated. For example, when the reference signal PGS is activated, the reference signal PGS may transition from a low level to a high level. For example, the monitoring operation circuit 131 may be configured to transfer the enable signal EN to the second counter 132 based on the rising edge of the reference signal PGS. For example, the enable signal EN received by the second counter 132 may be at a high level. For example, the second counter 132 may be configured to transfer the operation signal OP to the monitoring operation circuit 131 repeatedly with the first period, after the first time has elapsed since the enable signal EN is received. For example, the monitoring operation circuit 131 may be configured to perform the monitoring operation upon receiving the operation signal OP.

According to an embodiment, the monitoring operation circuit 131 may be configured to determine whether the result of the monitoring operation for the energy storage device 300 meets a first criterion. For example, the first criterion may be a criterion for upper and lower limits of the time period during which the charged voltage Vst drops from the first voltage to the second voltage.

For example, the monitoring operation circuit 131 may be configured to perform the monitoring operation repeatedly for a first count, based on whether the result of the monitoring operation meets the first criterion. For example, the monitoring operation circuit 131 may be configured to perform the monitoring operation repeatedly for the first count based on a determination that the result of the monitoring operation does not meet the first criterion.

For example, the monitoring operation circuit 131 may be configured to transfer a decision signal DS to the second counter 132 based on the determination that the result of the monitoring operation does not meet the first criterion. For example, the decision signal DS may be at a high level when the result of the monitoring operation meets the first criterion, and the decision signal DS may be at a low level when the result of the monitoring operation does not meet the first criterion. For example, the second counter 132 may be configured to transfer the operation signal OP to the monitoring operation circuit 131 repeatedly with a predetermined period for a first count, based on the decision signal DS. For example, the monitoring operation circuit 131 may be configured to receive the operation signal OP and perform the monitoring operation.

For example, when the second counter 132 does not receive the decision signal DS that the result of the monitoring operation meets the first criterion while performing the monitoring operation repeatedly for the first count, the second counter 132 may determine that the auxiliary power supply is abnormal. In this case, the charging circuit 100 may be configured to transfer, to the controller 400, the monitoring result signal MR indicating that the auxiliary power supply is abnormal.

The charging circuit 100 may be configured to transfer the monitoring result signal MR to a buffer memory 410 within the controller 400. By transferring the monitoring result signal MR to the buffer memory 410 of the controller 400, the monitoring result signal MR may be transferred without affecting the operation of the controller 400. By performing the monitoring operation and transferring the monitoring result signal MR without the control of the controller 400, the overhead of the controller 400 may be reduced.

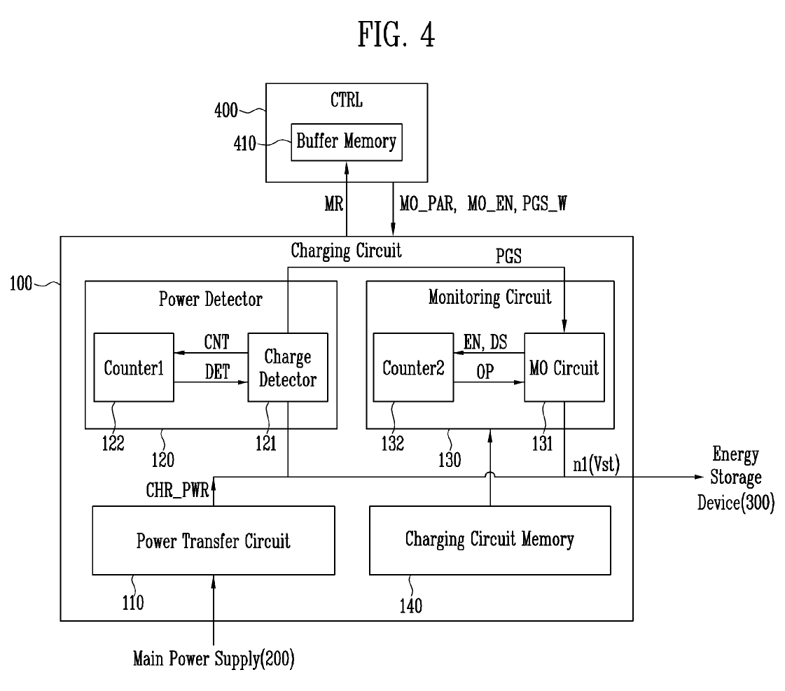

FIG. 4 is a diagram illustrating a case where the controller 400 controls the charging circuit 100, according to an embodiment of the present disclosure. For the sake of brevity, a detailed description of the previously-described components is omitted.

Referring to FIG. 4, the charging circuit 100 may further include a charging circuit memory 140. For example, the charging circuit memory 140 may be a volatile memory device.

According to an embodiment, the monitoring operation circuit 131 may be configured to perform the monitoring operation repeatedly with the first period, after the first time has elapsed since the charged voltage Vst exceeds the reference voltage. The monitoring operation circuit 131 may be configured to determine whether the result of the monitoring operation for the energy storage device 300 meets the first criterion. The monitoring operation circuit 131 may be configured to perform the monitoring operation repeatedly for the first count, based on whether the result of the monitoring operation meets the first criterion.

The charging circuit memory 140 may be configured to store the first time, the first period, the first criterion, and the first count. For example, when the charging circuit 100 is supplied with the charging power CHR_PWR by the main power supply 200, the monitoring circuit 130 may be configured to receive the first time, the first period, the first criterion, and the first count from the charging circuit memory 140. For example, the second counter 132 may be configured to receive the first time, the first period, the first criterion, and the first count from the charging circuit memory 140.

According to an embodiment, the controller 400 may be configured to transfer a monitoring parameter signal MO_PAR to the charging circuit 100. For example, the monitoring parameter signal MO_PAR may include at least one of a second time, a second period, a second criterion, or a second count. For example, the charging circuit memory 140 may be configured to update at least one of the first time, the first period, the first criterion, or the first count based on the monitoring parameter signal MO_PAR. For example, the charging circuit memory 140 may be configured to update at least one of the first time, the first period, the first criterion, or the first count to at least one of the second time, the second period, the second criterion, or the second count based on the monitoring parameter signal MO_PAR.

The charging circuit 100 may be configured to suspend or resume the monitoring operation based on an external interrupt signal or an external resume signal. The controller 400 may be configured to transfer a monitoring enable signal MO_EN to the charging circuit 100. For example, the charging circuit 100 may be configured to suspend or resume the monitoring operation based on the monitoring enable signal MO_EN.

According to an embodiment, the monitoring enable signal MO_EN may be at a low level when the controller 400 intends to suspend the monitoring operation. For example, the monitoring operation circuit 131 may be configured to transfer the low-level enable signal EN to the second counter 132 based on the monitoring enable signal MO_EN. The second counter 132 might not transfer the operation signal OP to the monitoring operation circuit 131 based on the low-level enable signal EN. For example, the second counter 132 may transfer the low-level operation signal OP to the monitoring operation circuit 131 based on the low-level enable signal EN.

According to an embodiment, the monitoring enable signal MO_EN may be at a high level when the controller 400 intends to resume the monitoring operation. For example, the monitoring operation circuit 131 may be configured to transfer the high-level enable signal EN to the second counter 132 based on the monitoring enable signal MO_EN. For example, based on the high-level enable signal EN, the monitoring operation circuit 131 may be configured to perform the monitoring operation. For example, the second counter 132 may be configured to transfer the operation signal OP to the monitoring operation circuit 131 repeatedly with the first period, after the first time has elapsed since the enable signal EN is received. For example, the second counter 132 may be configured to transfer the high-level operation signal OP repeatedly with the first period. For example, the charging circuit memory 140 may be configured to store the first time and the first period. For example, the monitoring operation circuit 131 may be configured to receive the operation signal OP and perform the monitoring operation.

The controller 400 may be configured to transfer a level control signal PGS_W to the charging circuit 100. For example, the charging circuit 100 may be configured to transition a voltage level of the reference signal PGS based on the level control signal PGS_W. For example, the charge detector 121 may be configured to transition the voltage level of the reference signal PGS based on the level control signal PGS_W. For example, the charging circuit 100 may be configured to suspend or resume the monitoring operation based on the transitioned reference signal PGS.

According to an embodiment, the monitoring operation circuit 131 may be configured to suspend or resume the monitoring operation based on the reference signal PGS received from the charge detector 121.

For example, the monitoring circuit 130 may be configured to suspend the monitoring operation based on the falling edge of the reference signal PGS. For example, based on the level control signal PGS_W, the charge detector 121 may transition the reference signal PGS from a high level to a low level. The monitoring circuit 130 may suspend the monitoring operation based on the falling edge of the reference signal PGS.

For example, the monitoring circuit 130 may be configured to perform the monitoring operation based on the rising edge of the reference signal PGS. For example, based on the level control signal PGS_W, the charge detector 121 may transition the reference signal PGS from a low level to a high level. The monitoring circuit 130 may start or resume the monitoring operation based on the rising edge of the reference signal PGS.

According to an embodiment, the monitoring operation circuit 131 may be configured to perform the monitoring operation repeatedly with the first period, after the first time has elapsed from the rising edge of the reference signal PGS. For example, based on the level control signal PGS_W, the charge detector 121 may transition the reference signal PGS from a low level to a high level. The monitoring circuit 130 may perform the monitoring operation repeatedly with the first period, after the first time has elapsed from the rising edge, based on the rising edge of the reference signal PGS.

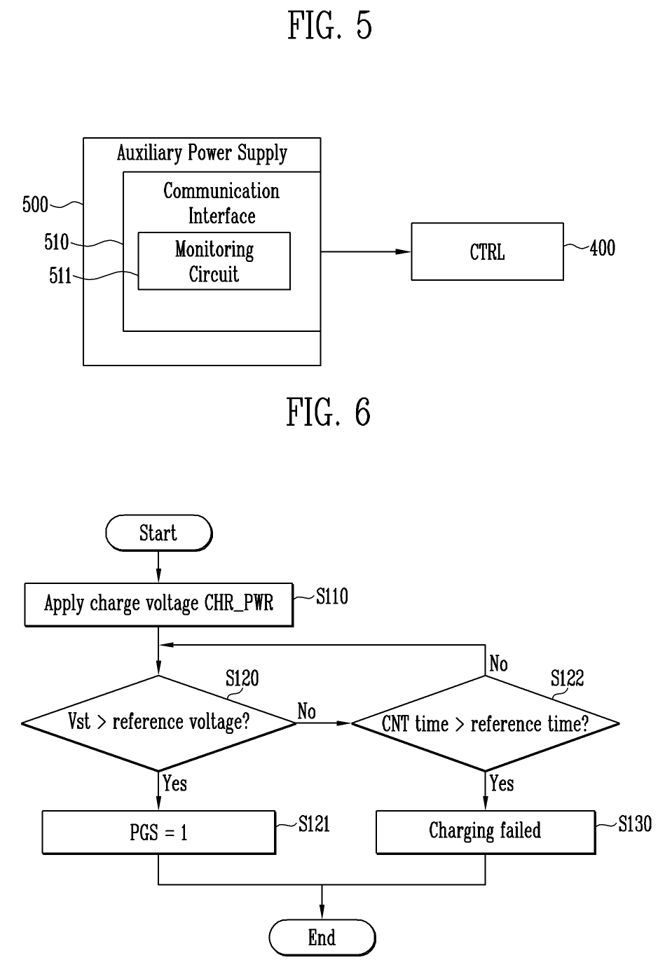

FIG. 5 is a diagram illustrating a method by which a monitoring circuit 511 communicates with the controller 400, according to an embodiment of the present disclosure.

According to an embodiment, an auxiliary power supply 500 may include a communication interface 510, and the communication interface 510 may include the monitoring circuit 511. For example, the monitoring circuit 511, by being implemented in the communication interface 510, may be configured to transfer a monitoring result signal directly to the controller 400 without the control of the controller 400.

According to an embodiment, the communication interface 510 operates based on a master-slave structure and may include one or more master devices and a plurality of slave devices. A master device is a device which controls a slave device, and a slave device is a device which operates under the control of the master device. For example, the controller 400 may operate as a master device and the auxiliary power supply 500 may operate as a slave device. For example, the controller 400 may be configured to control a bus and manage data communication with the auxiliary power supply 500 and other devices. The controller 400 may be configured to assign addresses and provide clock signals to the auxiliary power supply 500 and other devices, and transfer and receive data to and from the auxiliary power supply 500 and other devices. In addition, the controller 400 may be configured to monitor the status of the auxiliary power supply 500 and other devices and to transfer commands to the auxiliary power supply 500 and other devices when specific conditions are met.

According to an embodiment, the monitoring circuit 511 may be configured to issue an interrupt to the controller 400 upon the occurrence of specific events. For example, while communication pins are busy with ongoing communication between other devices, the monitoring circuit 511 may intervene and perform communication. For example, the communication interface 510 may support in-band interrupts to notify the master device of specific events, which allows the monitoring circuit 511 to perform event-based communication to the controller 400 on its own without the need for additional pins.

For example, the communication interface 510 may include one or more of interface devices based on a System Management Bus (SMBus), Inter-Integrated Circuit (I2C), or Improved Inter-Integrated Circuit (I3C) protocol.

FIG. 6 is a diagram illustrating a method by which a charging circuit generates a reference signal, according to an embodiment of the present disclosure. For the sake of brevity, a detailed description of the previously-described components is omitted. Hereinafter, descriptions are provided with reference to FIGS. 3 and 6 together.

At step S110, the charging power CHR_PWR may be supplied. For example, the power transfer circuit 110 may receive the charging power CHR_PWR output from the main power supply 200 and transfer (apply) the charging power CHR_PWR to the first node n1. For example, based on the charging power CHR_PWR transferred by the power transfer circuit 110, the energy storage device 300 may be charged with the auxiliary power.

At step S120, a checking operation may be performed to determine whether the charged voltage Vst of the energy storage device 300 by the auxiliary power is greater than a reference voltage. For example, the power detector 120 may check the voltage at the first node n1 to determine whether the charged voltage Vst is greater than the reference voltage. For example, the reference voltage may be set to a voltage which is less than the maximum charged voltage of the energy storage device 300. For example, when the charged voltage Vst is greater than the reference voltage, step S121 may be performed. Alternatively, when the charged voltage Vst is less than the reference voltage, step S122 may be performed.

At step S121, the high-level reference signal PGS may be generated. For example, the power detector 120 may determine that charging has proceeded normally when the charged voltage Vst is greater than the reference voltage. For example, the power detector 120 may generate the high-level reference signal PGS.

At step S122, it may be determined whether time information in the count signal CNT is greater than the reference time. For example, the power detector 120 may output the count signal CNT when the charged voltage Vst is less than the reference voltage. For example, the count signal CNT may include information about the time from when the charging power CHR_PWR begins to be supplied by the power transfer circuit 110 to when the charge detector 121 outputs the count signal CNT. For example, when the time information in the count signal CNT is greater than the reference time, step S130 may be performed. Alternatively, when the time information in the count signal CNT is less than the reference time, step S120 may be performed.

At step S130, it may be determined that the charging operation is abnormal. For example, the power detector 120 may compare the time information in the count signal CNT to the reference time to determine whether to continue performing the checking operation for determining whether the charged voltage Vst is greater than the reference voltage. For example, the power detector 120 may determine that the charging operation is abnormal when the checking operation for the charged voltage Vst has been performed for longer than the reference time. In this case, the power detector 120 may suspend the checking operation and determine that the auxiliary power supply is abnormal.

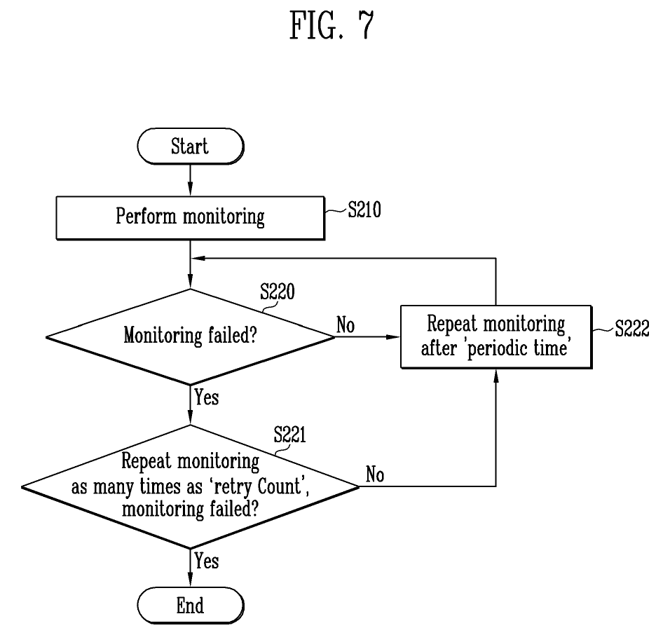

FIG. 7 is a diagram illustrating a method by which a charging circuit repeatedly performs a monitoring operation. For the sake of brevity, a detailed description of the previously-described components is omitted. Hereinafter, descriptions are provided with reference to FIGS. 3 and 7 together.

At step S210, a monitoring operation may be performed. For example, the monitoring circuit 130 may perform a monitoring operation on the energy storage device 300 when the charged voltage Vst exceeds a reference voltage. For example, the monitoring circuit 130 may perform the monitoring operation based on a rising edge of the reference signal PGS. For example, the monitoring circuit 130 may perform the monitoring operation after a first time has elapsed from the rising edge of the reference signal PGS.

At step S220, it may be determined whether the monitoring operation has failed. For example, the monitoring circuit 130 may perform the monitoring operation by measuring a storage capacity of the energy storage device 300, measuring a transfer efficiency, or measuring an energy loss value. For example, the monitoring circuit 130 may discharge the energy storage device 300, measure the time taken for the charged voltage Vst to drop from a first voltage to a second voltage, and perform the monitoring operation on the energy storage device 300. For example, the monitoring operation may be performed based on whether the time taken to drop from the first voltage to the second voltage is within a reference range. For example, when the monitoring operation has failed, step S221 may be performed. Alternatively, when the monitoring operation has not failed, step S222 may be performed.

At step S221, the monitoring circuit 130 may perform the monitoring operation repeatedly and determine whether the monitoring operation has failed. For example, the monitoring circuit 130 may perform the monitoring operation repeatedly up to a retry count. Based on the determination that the monitoring operation still fails after performing the monitoring operation repeatedly up to the retry count, the monitoring circuit 130 may determine that the energy storage device 300 is abnormal and terminate the operation. The monitoring circuit 130 may output the monitoring result signal MR including the determination that the energy storage device 300 is abnormal.

At step S222, the monitoring circuit 130 may perform the monitoring operation again after a predetermined period. For example, the monitoring circuit 130 may perform the monitoring operation repeatedly with a first period after step S210 is performed.

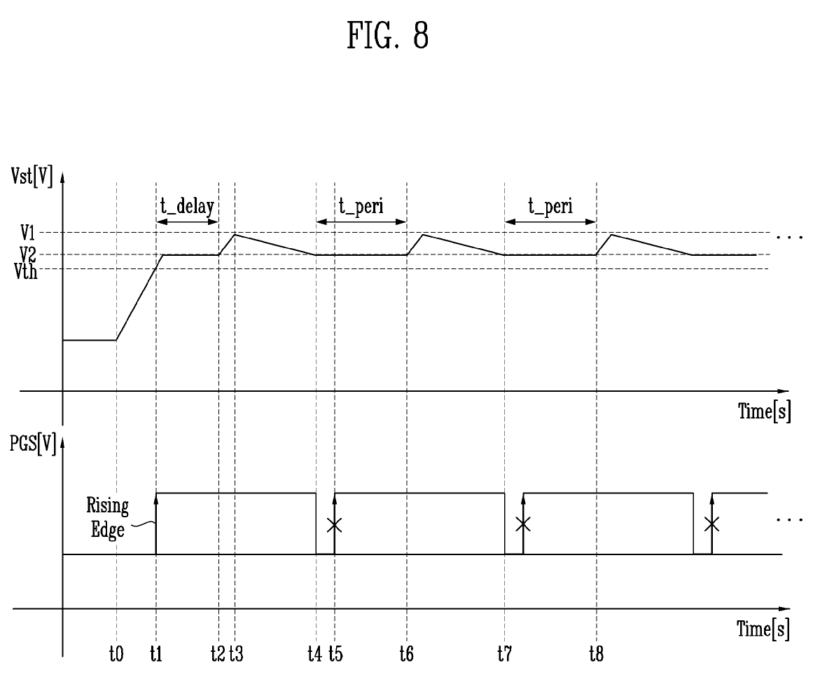

FIG. 8 is a diagram illustrating a voltage change in a charged voltage and a reference signal during a monitoring operation, according to an embodiment of the present disclosure. For the sake of brevity, a detailed description of the previously-described components is omitted. Hereinafter, descriptions are provided with reference to FIGS. 3 and 8 together.

Referring to FIG. 8, in the voltage graphs of the charged voltage Vst and the reference signal PGS, the x-axis may represent time and the y-axis may represent voltage. The voltage graphs of the charged voltage Vst and the reference signal PGS do not necessarily appear as shown in FIG. 8, and the voltage might not increase or decrease linearly.

In the period between time points t0 and t1, the charging power CHR_PWR may be supplied, causing the charged voltage Vst to increase. For example, the charging power CHR_PWR may be supplied to charge auxiliary power, and the charged voltage Vst may increase with the auxiliary power. At the time point t1, when the charged voltage Vst increases above a reference voltage Vth, the power detector 120 may transition the reference signal PGS from a low level to a high level. For example, the monitoring circuit 130 may detect a rising edge of the reference signal PGS.

In the period between time points t2 and t4, the monitoring circuit 130 may perform a monitoring operation. For example, the monitoring circuit 130 may perform the monitoring operation after a first time t_delay has elapsed since the charged voltage Vst exceeds the reference voltage Vth. For example, the monitoring circuit 130 may perform the monitoring operation after the first time t_delay from the rising edge of the reference signal PGS.

According to an embodiment, the monitoring circuit 130 may discharge the energy storage device 300 to perform the monitoring operation on the energy storage device 300 by measuring the time taken for the charged voltage Vst to drop from a first voltage V1 to a second voltage V2.

For example, in the period between the time points t2 and t3, the monitoring circuit 130 may control the energy storage device 300 to be charged further before discharging the energy storage device 300 so that the charged voltage Vst increases. For example, in the period between the time points t3 and t4, the monitoring circuit 130 may discharge the energy storage device 300 and measure the time taken for the energy storage device 300 to be discharged to determine the status of the energy storage device 300.

In the period between time points t4 and t5, the reference signal PGS may be toggled. For example, when the monitoring operation is completed, the monitoring circuit 130 may toggle the reference signal PGS to indicate the completion of the monitoring operation. For example, when the reference signal PGS is toggled upon completion of the monitoring operation, the monitoring circuit 130 might not respond to a rising edge of the reference signal PGS at the time point t5. For example, the monitoring circuit 130 might not perform a new monitoring operation based on the rising edge of the reference signal PGS at the time point t5.

The monitoring circuit 130 may perform the monitoring operation again after a predetermined period. For example, at the time point t4, the monitoring operation is completed, and at a time point t6 after a first period t_peri, the monitoring circuit 130 may perform the monitoring operation again. For example, at a time point t7, the monitoring operation is completed, and at a time point t8 after the first period t_peri from the time point t7, the monitoring circuit 130 may perform the monitoring operation again.

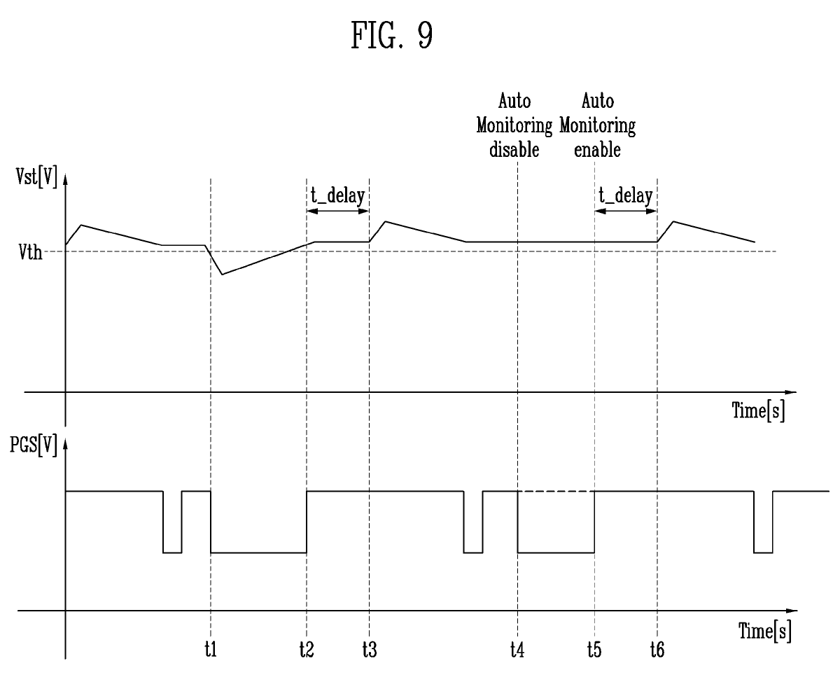

FIG. 9 is a diagram illustrating a voltage change in a charged voltage and a reference signal during a monitoring operation, according to an embodiment of the present disclosure. For the sake of brevity, a detailed description of the previously-described components is omitted. Hereinafter, descriptions are provided with reference to FIGS. 4 and 9 together.

Referring to FIG. 9, in the voltage graphs of the charged voltage Vst and the reference signal PGS, the x-axis may represent time and the y-axis may represent voltage. The voltage graphs of the charged voltage Vst and the reference signal PGS do not necessarily appear as shown in FIG. 9, and the voltage might not increase or decrease linearly.

At a time point t1, the charged voltage Vst may decrease to or below the reference voltage Vth. For example, the charged voltage Vst may decrease below the reference voltage Vth since the supplied power is temporarily interrupted or an error occurs during a monitoring operation. In this case, the monitoring circuit 130 may suspend the monitoring operation.

At a time point t2, the charged voltage Vst may increase above the reference voltage Vth. For example, the charged voltage Vst may increase back above the reference voltage Vth when the interrupted power supply is restored. In this case, the monitoring circuit 130 may detect that the charged voltage Vst increases above the reference voltage Vth. For example, the monitoring circuit 130 may detect a rising edge of the reference signal PGS.

At a time point t3, the monitoring circuit 130 may perform the monitoring operation. For example, the monitoring circuit 130 may perform the monitoring operation after the first time t_delay has elapsed since the charged voltage Vst exceeds the reference voltage Vth. For example, the monitoring circuit 130 may perform the monitoring operation after the first time t_delay from the rising edge of the reference signal PGS.

At a time point t4, the charging circuit 100 may suspend the monitoring operation based on an external interrupt signal. According to an embodiment, the controller 400 may transfer the monitoring enable signal MO_EN to the charging circuit 100. For example, the charging circuit 100 may suspend the monitoring operation based on the monitoring enable signal MO_EN. According to an embodiment, the controller 400 may transfer the level control signal PGS_W to the charging circuit 100. For example, the charging circuit 100 may transition the reference signal PGS based on the level control signal PGS_W. For example, based on the level control signal PGS_W, the reference signal PGS may transition from a high level to a low level. In this case, the monitoring circuit 130 may suspend the monitoring operation.

At a time point t5, the charging circuit 100 may resume the monitoring operation based on an external resume signal. According to an embodiment, the controller 400 may transfer the monitoring enable signal MO_EN to the charging circuit 100. For example, the charging circuit 100 may resume monitoring operation based on the monitoring enable signal MO_EN. According to an embodiment, the controller 400 may transfer the level control signal PGS_W to the charging circuit 100. For example, the charging circuit 100 may transition the reference signal PGS based on the level control signal PGS_W. For example, based on the level control signal PGS_W, the reference signal PGS may transition from a low level to a high level. In this case, the monitoring circuit 130 may resume the monitoring operation based on the rising edge of the reference signal PGS. For example, the monitoring circuit 130 may perform the monitoring operation at a time point t6 after the first time t_delay has elapsed from the time point t5.

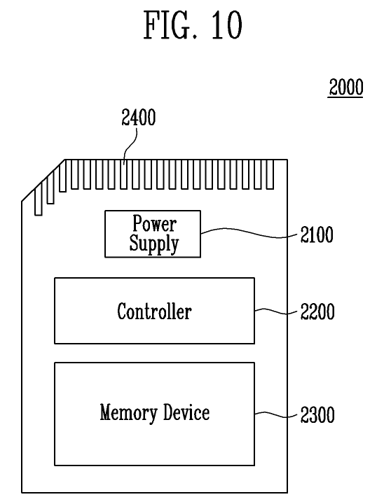

FIG. 10 is a diagram illustrating a memory card system 2000 to which a power supply 2100 is applied, according to an embodiment of the present disclosure.

Referring to FIG. 10, the memory card system 2000 includes the power supply 2100, a controller 2200, a memory device 2300, and a connector 2400.

The power supply 2100 may be configured in the same manner as the power system 1000 shown in FIG. 2, and may supply main power or auxiliary power to the controller 2200 and the memory device 2300. For example, the power supply 2100 may include the charging circuit 100 of FIG. 3.

The controller 2200 is coupled to the memory device 2300. The controller 2200 may be configured to access the memory device 2300. For example, the controller 2200 may be configured to control a program, read, or erase operation of the memory device 2300, or to control a background operation. The controller 2200 may be configured to provide an interface between the memory device 2300 and a host. The controller 2200 may be configured to drive firmware for controlling the memory device 2300. For example, the controller 2200 may include components such as Random Access Memory (RAM), a processing unit, a host interface, a memory interface, and an error correction unit.

The controller 2200 may communicate with an external device via the connector 2400. The controller 2200 may communicate with an external device (e.g., a host) based on a specific communication protocol. For example, the controller 2200 may communicate with the external device through at least one of various communication protocols such as a Universal Serial Bus (USB), a Multi-Media Card (MMC), an embedded MMC (eMMC), a Peripheral Component Interconnect (PCI), PCI-Express (PCI-e), Advanced Technology Attachment (ATA), Serial-ATA (SATA), Parallel-ATA (PATA), a Small Computer System Interface (SCSI), an Enhanced Small Disk Interface (ESDI), Integrated Drive Electronics (IDE), Firewire, Universal Flash Storage (UFS), Wi-Fi, Bluetooth, and/or Non-Volatile Memory express (NVMe). For example, the connector 2400 may be defined by at least one of the above-described various communication protocols.

For example, the memory device 2300 may include various non-volatile memory elements, such as Electrically Erasable and Programmable ROM (EEPROM), NAND flash memory, NOR flash memory, Phase-change RAM (PRAM), Resistive RAM (ReRAM), Ferroelectric RAM (FRAM), and/or Spin-Transfer Torque Magnetic RAM (STT-MRAM).

The controller 2200 and the memory device 2300 may be integrated into a single semiconductor device to form a memory card. For example, the controller 2200 and the memory device 2300 may be integrated into a single semiconductor device to form a memory card, such as a Personal Computer Memory Card International Association (PCMCIA), a Compact Flash (CF) card, a smart media card (SM, SMC), a memory stick, a Multi-Media Card (MMC, RS-MMC, MMCmicro, eMMC), an SD card (SD, miniSD, microSD, SDHC), Universal Flash Storage (UFS), or the like.

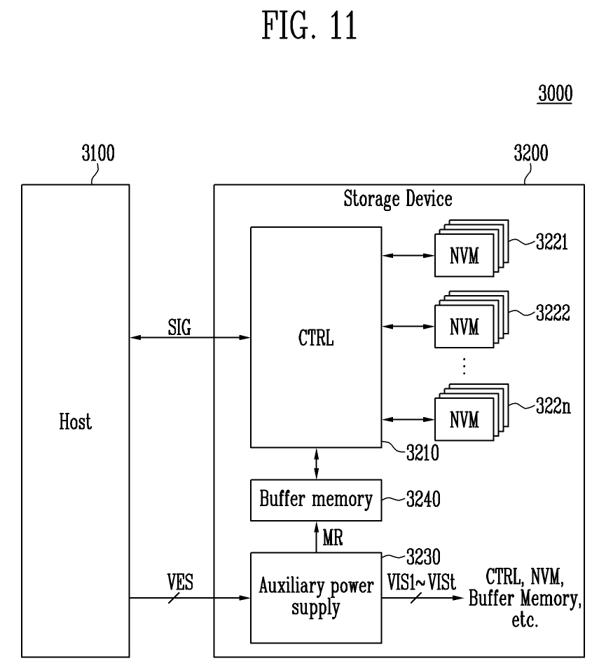

FIG. 11 is a diagram illustrating a storage system 3000 to which a power supply is applied, according to an embodiment of the present disclosure.

Referring to FIG. 11, the storage system 3000 includes a host 3100 and a storage device 3200. The storage device 3200 may transfer and receive a signal SIG to and from the host 3100 and may receive the power VES. The storage device 3200 includes a controller 3210, a plurality of flash memories (Non-Volatile Memory (NVM)) 3221 to 322n, an auxiliary power supply 3230, and a buffer memory 3240.

The controller 3210 may control the plurality of flash memories 3221 to 322n in response to the signal SIG received from the host 3100. For example, the signal SIG may be a signal based on interfaces of the host 3100 and the storage device 3200. For example, the signal SIG may be defined by at least one of communication standards or interfaces such as Universal Serial Bus (USB), Multi-Media Card (MMC), embedded MMC (eMMC), Peripheral Component Interconnect (PCI), PCI-Express (PCI-e), Advanced Technology Attachment (ATA), Serial-ATA, Parallel-ATA, Small Computer System Interface (SCSI), Enhanced Small Disk Interface (ESDI), Integrated Drive Electronics (IDE), Firewire, Universal Flash Storage (UFS), Wi-Fi, Bluetooth, or NVMe interfaces.

The auxiliary power supply 3230 may be implemented in the same or similar manner to the auxiliary power supply 20 described with reference to FIG. 2. For example, the auxiliary power supply 3230 may include the charging circuit 100 of FIG. 3. For example, the auxiliary power supply 3230 may receive the power VES from the host 3100 and may be charged. The auxiliary power supply 3230 may provide the internal voltages VIS1 to VISt to the storage device 3200 when the supply of the power VES from the host 3100 is not smooth (for example, determined based on fluctuations, variation beyond predetermined measures based on voltage, time, frequency, etc.). For example, the auxiliary power supply 3230 may be located within the storage device 3200 or may be located outside of the storage device 3200. For example, the auxiliary power supply 3230 may be located on a main board and may provide auxiliary power to the storage device 3200.

The buffer memory 3240 operates as a buffer memory for the storage device 3200. For example, the buffer memory 3240 may temporarily store data received from the host 3100 or data received from the plurality of flash memories 3221 to 322n, or may temporarily store metadata (e.g., a mapping table) of the plurality of flash memories 3221 to 322n. The buffer memory 3240 may include a volatile memory, such as DRAM, SDRAM, DDR SDRAM, LPDDR SDRAM, or the like, or a non-volatile memory, such as FRAM, ReRAM, STT-MRAM, PRAM, or the like.

According to an embodiment, as described above with reference to FIGS. 3 and 4, the auxiliary power supply 3230 may transfer the monitoring result signal MR to the buffer memory 3240. By transferring the monitoring result signal MR to the buffer memory 3240 of the storage device 3200, the monitoring result signal MR may be transferred without affecting the operation of the controller 3210. By performing the monitoring operation and transferring the monitoring result signal MR without the control of the controller 3210, the overhead of the controller 3210 may be reduced.

According to an embodiment, the controller 3210 may determine whether to utilize the auxiliary power supply 3230 based on the supply of the external power VES and the monitoring result signal MR. For example, the controller 3210 may be supplied with the internal voltages VIS1 to VISt from the auxiliary power supply 3230 when the supply of the power VES from the host 3100 is not smooth and the monitoring result signal MR indicates a normal state. For example, the controller 3210 might not be supplied with the internal voltages VIS1 to VISt from the auxiliary power supply 3230 when the monitoring result signal MR indicates an abnormal state.

According to an embodiment, the controller 3210 may be configured to determine whether to utilize the buffer memory 3240 based on the monitoring result signal MR. For example, the controller 3210 may utilize the buffer memory 3240 when the monitoring result signal MR indicates the normal state, and might not utilize the buffer memory 3240 when the monitoring result signal MR indicates the abnormal state. For example, the controller 3210 may change a mode of the storage device 3200 from a write-back mode to a write-through mode during a write operation.

For example, a write operation mode may be a write-back mode or a write-through mode. The write-back mode may refer to a data write method in which data is first written to the buffer memory 3240, and then the data stored in the buffer memory 3240 is written to the flash memories 3221 to 322n only when needed, allowing data to be written during idle periods. The write-through mode may refer to a data write method in which data is written to both the buffer memory 3240 and the flash memories 3221 to 322n simultaneously in parallel, allowing an immediate write operation without idle delay. When the auxiliary power supply 3230 is in a normal state, the write-back mode, which is more efficient, may be used. However, when the auxiliary power supply 3230 is in an abnormal state, operating in the write-back mode may result in data loss. Therefore, the controller 3210 may change the write operation mode to the write-through mode to minimize or reduce data loss.

As used herein, the term “device” or “unit” refers to any combination of software, firmware, and/or hardware configured to provide the functionality described herein. For example, the software may be implemented as a software package, code, and/or instruction set or a command, and the hardware may include, for example, a single or any combination or assembly of a hardwired circuit, programmable circuit, state machine circuit, and/or firmware storing a command executed by the programmable circuit.

Embodiments of the present disclosure may provide a power supply device which performs a monitoring operation on an auxiliary power supply without the control of a controller by performing monitoring of the auxiliary power supply based on a charged voltage stored in the auxiliary power supply.

What is claimed is:

1. A power supply device comprising:
a main power supply configured to be supplied with external power to output charging power and main power;
an auxiliary power supply configured to be charged with the charging power to output auxiliary power; and
a charging circuit configured to measure a charged voltage based on the auxiliary power, and
perform, when the charged voltage exceeds a reference voltage, a monitoring operation on the auxiliary power to generate a monitoring result.

2. The power supply device of claim 1, wherein the monitoring operation includes discharging the auxiliary power supply and measuring a time taken for the charged voltage to drop from a first voltage to a second voltage.

3. The power supply device of claim 1, wherein the charging circuit is configured to transfer the monitoring result to an external buffer memory.

4. The power supply device of claim 1, wherein the charging circuit is configured to perform the monitoring operation repeatedly with a first period, after a first time has elapsed since the charged voltage exceeds the reference voltage.

5. The power supply device of claim 4, wherein the charging circuit includes a memory device configured to:
store the reference voltage, the first time, and the first period; and
update one or more of the reference voltage, the first time, or the first period based on an external signal.

6. The power supply device of claim 4, wherein the charging circuit is configured to:
determine whether the monitoring result meets a first criterion; and
perform, based on the determination, the monitoring operation repeatedly for a first count.

7. The power supply device of claim 6, wherein the charging circuit includes a memory device configured to:
store the first criterion and the first count; and
update one or more of the first criterion or the first count based on an external signal.

8. The power supply device of claim 1, wherein the charging circuit is configured to suspend or resume the monitoring operation, based on an external signal.

9. The power supply device of claim 1, wherein the auxiliary power supply includes a plurality of capacitors configured to output the auxiliary power.

10. The power supply device of claim 1, further comprising a switch circuit configured to:
be activated based on the monitoring result; and
output the auxiliary power when supply of the external power is interrupted.

11. A method of operating a power supply device, the method comprising:
charging auxiliary power in an auxiliary power supply using charging power applied to the auxiliary power supply;
comparing charged voltage based on the auxiliary power with a reference voltage to activate a reference signal; and
performing, according to activation of the reference signal, a monitoring operation on the auxiliary power supply to generate a monitoring result.

12. The method of claim 11, wherein performing the monitoring operation comprises:
discharging the auxiliary power supply; and
measuring a time taken for the charged voltage to drop from a first voltage to a second voltage.

13. The method of claim 11, further comprising transferring the monitoring result to an external buffer memory.

14. The method of claim 11, wherein performing the monitoring operation comprises:
performing the monitoring operation repeatedly with a first period, after a first time has elapsed since the reference signal is activated;
determining whether the monitoring result meets a first criterion; and
performing the monitoring operation repeatedly for a first count, based on the determining.

15. The method of claim 14, further comprising updating one or more of the reference voltage, the first time, the first period, the first criterion, or the first count based on an external signal.

16. The method of claim 11, wherein comparing the charged voltage comprises transitioning the reference signal from a first level to a second level to activate the reference signal, and
wherein performing the monitoring operation comprises performing the monitoring operation on the auxiliary power supply based on the activation of the reference signal.

17. The method of claim 16, further comprising:
suspending the monitoring operation, based on an external interrupt signal or deactivation of the reference signal; and
resuming the monitoring operation, based on an external resume signal or the activation of the reference signal.

18. A power system comprising:
a main power supply configured to be supplied with external power to output charging power and main power;
an auxiliary power supply configured to be charged with the charging power to output auxiliary power;
a charging circuit configured to measure a charged voltage based on the auxiliary power, perform, when the charged voltage exceeds a reference voltage, a monitoring operation on the auxiliary power to generate a monitoring result; and
a controller configured to control the charging circuit.

19. The power system of claim 18,
wherein the controller includes a buffer memory, and
wherein the charging circuit is configured to transfer the monitoring result to the buffer memory.

20. The power system of claim 19, wherein the controller is configured to determine, based on the monitoring result, whether to utilize the buffer memory during a program operation.
